(19) United States
(12) Patent Application Publication
(10) Pub. No.: US 2014/0365021 A1
(43) Pub. Date: Dec. 11, 2014

(54) System and Method of Monitoring an Irrigation System

(71) Applicant: Kyle Workman, Jewett, TX (US)

(72) Inventor: Kyle Workman, Jewett, TX (US)

(21) Appl. No.: 13/911,060

(22) Filed: Jun. 5, 2013

(51) Int. Cl. A01G 25/16; G01R 31/06

(52) U.S. Cl. CPC A01G 25/16; G01R 31/06
USPC 700/284; 324/546

(57) ABSTRACT

A monitoring system is configured to monitor electrical signals in an irrigation system. The monitoring system includes a memory and a detector coupled to an irrigation control line that is configured to provide control signals to an actuator within the irrigation system. The detector is configured to sense an electrical parameter of the control signals and to store data related to the electrical parameter in the memory.

### FIELD

The present disclosure is generally related to electronically controlled irrigation systems that deliver water to grass, shrubs, trees, plant, and other landscaping.

### BACKGROUND

Automated irrigation systems for irrigation of residential and commercial landscapes typically include irrigation control systems that can control one or more electrically controllable valves independently to individually water a number of irrigation zones on a property. The zones may have different watering requirements in accordance with location, soil composition, sun exposure, vegetation and seasonal climatological factors. Accordingly, the irrigation control systems may be programmed to activate valves to deliver water at pre-determined times and for different durations, depending on the zone, to sprinklers configured to distribute the water to landscape areas.

The irrigation controller may include dials, buttons, or other interface elements to facilitate configuration of the irrigation settings, including start time and duration of watering. Each zone includes a plurality of sprinkler heads and/or drip lines coupled by supply lines to the electrically-controlled valve associated with that zone. The irrigation controller may be coupled to the electrically-controlled valves by control lines. Each of the electrically-controlled valves includes an actuator (such as a solenoid) that is responsive to a control signal from the irrigation controller to selectively open or close the valve according to the schedule programmed into the irrigation controller, to selectively deliver water to the particular zone.

Contractors who install automated irrigation systems may program the irrigation controller to include on-times that are particular to each zone. In some instances, such contractors may be required to replace plants if the plants die due to lack of irrigation even if the cause of the problem cannot be verified.

### SUMMARY

In an embodiment, a monitoring system is configured to monitor electrical signals in an irrigation system. The monitoring system includes a memory and a detector coupled to an irrigation control line that is configured to provide control signals to an actuator within the irrigation system. The detector is configured to sense an electrical parameter of the control signals and to store data related to the electrical parameter in the memory.

In another embodiment, an irrigation system includes an irrigation controller coupled to a plurality of irrigation control lines and configured to selectively apply control signals to one or more of the plurality of irrigation control lines to selectively activate a plurality of watering zones of an irrigation system. The irrigation system further includes a monitoring system coupled to the plurality of irrigation control lines. The monitoring system includes a memory and at least one sensor. The monitoring system is configured to sense at least one electrical parameter associated with the plurality of irrigation control lines during an irrigation operation using the at least one sensor and to store data corresponding to the at least one electrical parameter in the memory.

In still another embodiment, a method of monitoring an irrigation system includes measuring at least one electrical parameter associated with a signal on a control line of an irrigation system. The method further includes recording data corresponding to the at least one electrical parameter in a memory.

### BRIEF DESCRIPTION OF THE DRAWINGS

FIG. 1 is a block diagram of an irrigation system including an irrigation controller and an external monitoring system according to an embodiment.

FIG. 2 is a block diagram of the irrigation system of FIG. 1 including an expanded view of the irrigation controller and the monitoring system according to an embodiment.

FIG. 3 is a block diagram of a portion of the irrigation system according to an embodiment.

FIGS. 4A-4C are diagrams of a portion of the monitoring system of FIGS. 1 and 2, including a current detector (4A), a voltage detector (4B), and a power detector (4C) according to embodiments.

FIG. 5 is a block diagram of an irrigation system including an irrigation controller and an embedded monitoring system according to a second embodiment.

FIG. 6 is a block diagram of the irrigation systems of FIGS. 1-3, and 5 including a transceiver configured to communicate with an external device via a network according to an embodiment.

FIG. 7 is a flow diagram of an embodiment of a method of recording data corresponding to an electrical parameter of the irrigation system according to an embodiment.

FIG. 8 is a flow diagram of a method of providing measurement data and associated time data from an irrigation system to a remote device according to an embodiment.

FIG. 9 is a flow diagram of a method of selectively generating an alert in response to detecting a deviation in the measurement data of an irrigation system according to an embodiment.

FIG. 10 is a flow diagram of a method of generating an alert in response to detecting a state of one of an actuator and a valve of an irrigation system according to an embodiment.

In the following discussion, the same reference numbers are used in the various embodiments to indicate the same or similar elements.

### DETAILED DESCRIPTION OF ILLUSTRATIVE EMBODIMENTS

Embodiments of a monitoring system are described below that are configurable to provide data logging capabilities for monitoring control signals provided to electrically-controlled valves of an irrigation system. The monitoring system is configurable to monitor execution of watering schedules implemented by homeowners, commercial building operators, landscape maintenance contractors, and the like. The control signals individually activate selected valves of the irrigation system to deliver water to sprinkler heads or other water delivery mechanisms (such as drip lines, misters, and/or other water delivery components) at a prescribed time and for a prescribed duration. The monitoring system may be configured to measure one or more electrical parameters of control signals sent by an irrigation controller to actuators (such as solenoids) coupled to valves of the irrigation system. The monitoring system may be further configured to determine timing and duration of such signals. In an embodiment, the monitoring system records data corresponding to the measured electrical parameters and the associated timing and duration information in a memory. The monitoring system includes a data port, such as a universal serial bus (USB) port, a wireless transceiver, other communications circuitry, or any combination thereof, that is configurable to communicate the stored data to an external device, such as a smart phone, another portable computing device, and/or a remote device through a network.

In an embodiment, in addition to storing the measurement data and associated timing and duration data, the monitoring system may be configured to detect an anomaly, such as a peak current drawn by a solenoid that exceeds a current threshold, a duration of an in-rush current that exceeds an in-rush time threshold, a total power consumption of a particular solenoid valve that exceeds a threshold, and so on. In an example, a valve control signal may have a typical signal profile. The signal profile may include a first portion corresponding to a valve actuating operation and a second portion corresponding to a holding operation. The first portion may have a first voltage level and first current draw and the second portion may have a second voltage level and a second current draw. In one particular example, the first voltage level and first current draw are both higher than the second voltage level and the second current draw. For a valve that is functioning correctly, the valve control signal may be controllable by a signal having a first signal profile. As the valve begins to malfunction, the valve control signal may change, such as by drawing the first current longer than normal or by drawing more power over time. In another example, the monitoring system may be configured to detect an anomaly such as a low current draw (i.e., a current that is below a pre-determined current threshold), which may indicate that the valve is stuck in an open position.

In some embodiments, in response to detecting an anomaly, the monitoring system may be configured to generate and transmit an alert to a remote device through a communications network (such as a cellular network or a short or long-range wired or wireless communication network), allowing a user or corporation to monitor an irrigation system remotely, to detect possible problems early, and to mitigate such problems before landscape elements, such as trees, shrubs, grass, flowers, and the like, suffer damage. The data collection (logging) and communications capabilities provide accountability of watering schedules for the use of the homeowner, commercial building managers, city/water service providers, and/or individual or entity interested in providing oversight as to the schedule watering times, durations, etc. of landscape irrigation systems.

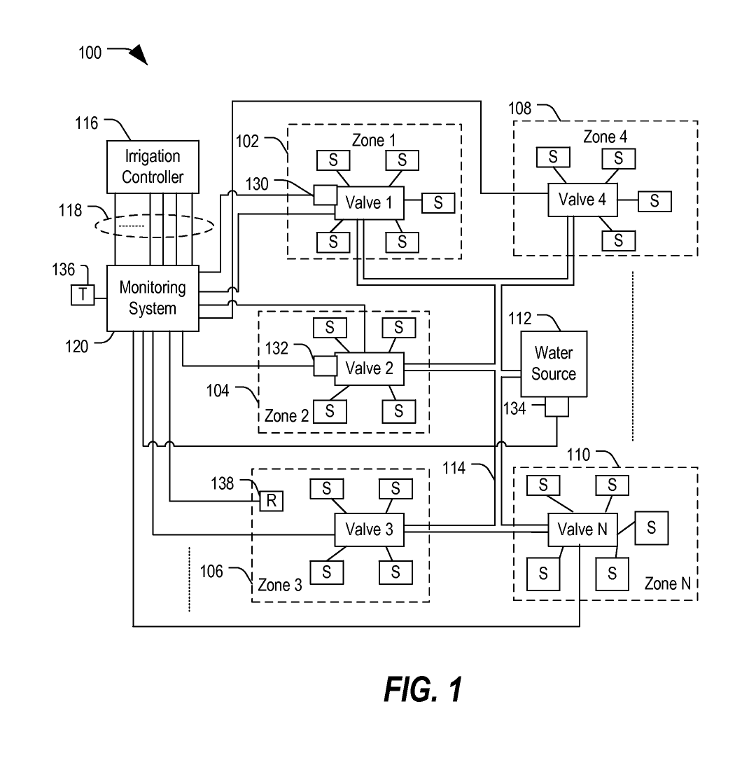

In general, the monitoring system may be provided within the housing of the irrigation controller or may be implemented in a separate weather-tight enclosure. In a particular embodiment, the housing of the monitoring system may be formed of plastic or composite materials with threaded polyvinyl chloride (PVC) connections for leads in, leads out, power source(s), and accessories. Inside the enclosure, the monitoring system includes a data logging device, which may include a plurality of screw-head connectors similar to a bus-bar or electrical distribution block. The data logging device includes a sensor that captures data corresponding to at least one electrical parameter (i.e., current, voltage, impedance, etc.) and provides the data to a processor, which is configured to associate the data with corresponding timing information including the start time and duration of the electrical parameter of the signal that is sent to each irrigation valve. The data may be stored in a memory, such as a flash memory, a hard disk, an internal microchip, an external jump drive or flash drive, a secure digital high-capacity (SDHC) card, or other memory device. Additionally, the data may be transmitted to a remote system or external device for storage. The data can be accessed by a processor, a smart phone, or computing device, such as a laptop or tablet computing device via a USB cable or a wireless communication link, such as a Bluetooth® communications link or other wireless communication link. In some embodiments, the data may be accessed or accessible through a network. One possible embodiment of a monitoring system is described below with respect to FIG. 1.

FIG. 1 is a block diagram of a first embodiment of an irrigation system 100 including an irrigation controller 116 and an external monitoring system 120 configured to monitor an electrical parameter associated with the control lines 118 from the irrigation controller 116. Irrigation system 100 includes multiple irrigation zones 102, 104, 106, 108, and 110 (labeled “Zone 1”, “Zone 2”, “Zone 3”, “Zone 4”, and “Zone N”). While only five zones are depicted, any number (N) zones may be included. Each irrigation zone 102, 104, 106, 108, and 110 includes at least one electrically controllable valve that is coupled to one or more water distribution components, such as sprinkler heads, drip lines, sprayers, other irrigation components, or any combination thereof. Each valve may include an actuator, such as a solenoid, that may be controlled by electrical signals to open and/or close the valve to control water flow to each of the connected water distribution components. In the illustrated example, each valve is connected to a plurality of sprinkler heads (labeled “S”), which represent water distribution components that may be distributed throughout a zone to be watered. Each valve is also coupled to a water source 112 by a pressurized conduit. In most residential and commercial settings, the water source 112 may represent a metered water line. In some instances, the water source 112 may represent a pressured line from a private well.

In the illustrated example, monitoring system 120 is implemented as a mid-span device coupled to control lines 118 between irrigation controller 116 and each of zones 102, 104, 106, 108, and 110. Control lines 118 represent conductive wires extending from irrigation controller 116 to an electrically-controlled valve and a return current flow path from the electrically-controlled valve to irrigation controller 116.

Monitoring system 120 is coupled to control lines 118 and is configured to measure an electrical parameter, such as current, voltage, power, impedance, some other electrical parameter, or any combination thereof. Monitoring system 120 is configured to monitor electrical signals sent to each zone 102, 104, 106, 108, and 110. In particular, monitoring system 120 measures the electrical parameter of a control signal sent by irrigation controller 116 to a particular zone, such as zone 102, recording the electrical parameter, date, start time, end time, and zone identifier information in a memory. The zone identifier may include a zone number or other identifier used to differentiate the zone from other zones of the irrigation system. Monitoring system 120 measures and records such information for each zone, making it possible for a user or administrator to review the data at a later time to determine if irrigation system 116 may have been turned off, disconnected, malfunctioning, etc. or if there may be a problem with settings and/or with hardware of the irrigation controller or of one or more of the zones.

Monitoring system 120 may be configured to store data for a multiple zones and for an extended period of time. In one example, monitoring system may be configured to store a minimum of 365 days-worth of irrigation system data for each zone. This duration may be selected to correspond, for example, to an installer's warranty. In an embodiment, monitoring system stores the date, start time, and end time of each control signal for each zone. Further, monitoring system 120 may store peak current, peak voltage, average current, average voltage, or other electrical parameter information. In a particular embodiment, monitoring system 120 may capture multiple samples or measurements during a period of time, such as during a period in which the particular zone is activated to deliver water.

For example, sprinkler valves may include a solenoid that is activated by a first current, causing the solenoid to open the valve. Once the valve is open, the solenoid may maintain the valve in an open state in response to a second (holding) current. The second current may be less than the first current. Once irrigation controller 116 turns off a drive signal to the particular solenoid, the solenoid may close the valve. When sampled multiple times over an operating period, the drive current provided by irrigation controller 116 may present a signature, which remains substantially consistent over time and which begins to vary either when the solenoid begins to fail or when the valve begins to stick. In either case, the signature determined from multiple samples of the drive current may be used as a valve signature that can be compared to a current signal profile to provide an early indication of valve and/or solenoid failure.

In an embodiment, monitoring system 120 may store date and time data corresponding to power outage(s) as well as the date/time information corresponding to when the data has been accessed, either through a wired (physical) download or a wireless download. Further, in some embodiments, monitoring system 120 may be coupled to additional sensors 130, 132, and 134 that can measure flow or sense moisture at one or more of the valves and/or monitor water flow at the meter or water source 120. Further, monitoring system 120 may be coupled to additional sensors, such as a temperature sensor 136 (labeled “T”), and/or a moisture sensor 138, such as a rain sensor (labeled “R”). The temperature and moisture measurements may also be recorded with date and time stamps.

Monitoring system 120 may include a processor configured to capture measurement data and store the data in a memory. The measurement data may be raw data samples or may be groomed or scaled prior to storage. Monitoring system 120 may be configured to process the measurement data and to detect anomalies in the measurement data to determine when a valve is not working properly (or is beginning to experience problems) and may generate an alert that can be communicated to an external or remote device through a wired or wireless communications link.

Alternatively, monitoring system 120 may provide the raw measurement data, date, and timing information to an external device when the external device is connected to monitoring system 120 or when the external device negotiates a wireless communication link with monitoring system 120. In a particular embodiment, monitoring system 120 may be removed by the installer and repurposed for use in future project(s), for example, after a warranty period expires or when a maintenance contract is terminated.

In a particular example, a contractor may provide a warranty with respect to an irrigation system and landscape elements. The contractor may install the monitoring system as an external component coupled to the irrigation controller 116 to monitor operation of the irrigation system 100. Monitoring system 120 may monitor and log control signals sent to one of more of the irrigation zones, recording signal information and associated date, time and duration information in a memory. The contractor may access monitoring system 120 periodically either through a direct connection or a network connection (wired or wireless) to download the data and associating timing information. The contractor may then use that information to provide an early warning that certain zones are not working properly or to determine when a property manager or owner has altered the watering schedule in some way, possibly voiding the warranty. If a problem arises, the contractor may interact with a USB port or other interface of the monitoring system 120 to verify problems. When the warranty period expires, the contractor may remove monitoring system 120, allowing the contractor to repurpose the monitoring system 120 by installing it with a different irrigation system at another location.

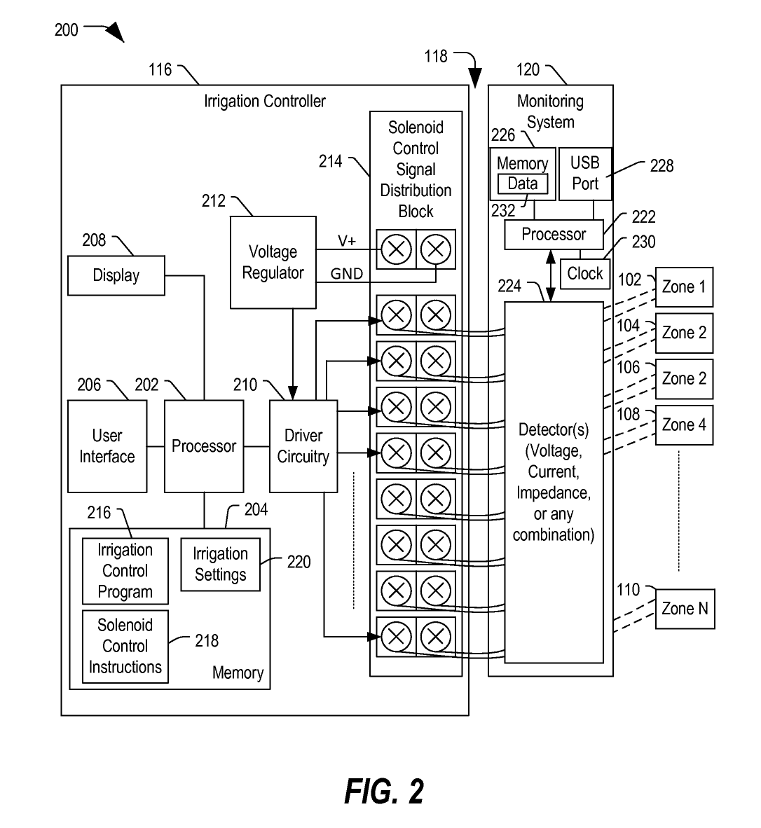

Monitoring system 120 may be implemented in a variety of ways. One possible example of a monitoring system 120 that includes a processor is described below with respect to FIG. 2.

FIG. 2 is a block diagram of an irrigation system 200, such as the irrigation system 100 of FIG. 1, including an expanded view of the irrigation controller 116 and the monitoring system 120 according to an embodiment. Irrigation controller 116 includes a processor 202 coupled to a memory 204 and to a display 208. Irrigation controller 116 further includes a user interface 206 (such as a keypad) coupled to processor 202. Additionally, irrigation controller 116 includes driver circuitry 210 coupled to zones 102, 104, 106, 108, and 110 through connectors of a solenoid control signal distribution block 214, control lines 118, and monitoring system 120. Irrigation controller 116 further includes a voltage regulator 212 coupled to solenoid control signal distribution block 214 to provide a power supply and a ground connection.

Solenoid control signal distribution block 214 includes a plurality of connectors, such as screws and corresponding conductive pads, which may be used to secure an exposed end of a wire extending between irrigation controller 116 and the electrically controllable valves in zones 102, 104, 106, 108, and 110. Alternatively, the screws and conductive pads of solenoid control signal distribution block 214 may couple wires from monitoring system 120 to irrigation controller 116. Though solenoid control signal distribution block 214 is depicted as including a plurality of screws, other types of fasteners may also be used, such as clips or clamps.

Monitoring system 120 includes a processor 222 coupled to a plurality of detectors 224, which may include voltage, current, and/or impedance sensors. Processor 222 is also coupled to a memory 226, which stores instructions executable by processor 222 and which stores data 232. Memory 226 may be a hard disk drive, a flash drive, or other non-volatile memory accessible to a processor 222 and configurable to record the data 232 and instructions. Data 232 corresponds to a measured electrical parameter as well as date, time, and duration data. Monitoring system 120 further includes a USB port 228 and a clock 230, which are both coupled to processor 222.

Irrigation system 200 includes zones 102, 104, 106, 108 and 110, which may be connected directly to irrigation controller 116 through solenoid control signal distribution block 214. Alternatively, zones 102, 104, 106, 108, and 110 may be coupled to irrigation controller 116 through monitoring system 120. In an embodiment, monitoring system 120 may include a distribution block similar to solenoid control signal distribution block 214, and detectors 224 may be coupled between connectors of the distribution block to sense the electrical parameters.

Memory 226 includes software that, when executed, causes processor 222 to capture measurement data from detectors 224, to receive timing information from clock 230, and to record the measurement data, date, time, and duration information in memory 226 as data 232. The measurement data may include a voltage, a current, or another electrical measurement. In an embodiment, the software may be proprietary software that may be configured to parse the data and to present the in charts, graphs, or table format(s). Data may be presented on a display of monitoring system 120 or on a display of irrigation controller 116. Alternatively, the data may be provided to an external device, which may include a display. In an example, a user may connect a portable memory device (such as a thumb drive or flash memory device) or a portable computing device, such as smart phone, tablet computer, laptop computer, or other data processing device, to USB port 228 to retrieve data 232.

In an embodiment, monitoring system 120 may be provided within a locked enclosure, which includes a lock and a corresponding key that can be retained by an administering entity, such as the installer, a municipality, a company, or an individual responsible for operation of the irrigation system 200. In a particular embodiment, the enclosure may be a water-tight enclosure that may be installed indoors or outside and that may include a cover that may be opened to access USB port 228 and/or to replace components. In an embodiment, the access key may be a configurable combination, and the locking mechanism may be a built-in combination lock.

In another embodiment, the access key may be a semi-unique key having a key shape configured to fit a particular type of lock. The housing may be configured with a selected one a pre-determined set of locks that fits a corresponding one of a set of key profiles (such as 10 key profiles). In a particular example, the housings may be constructed with a selected one of the set of locks, selected at random. In an example, a number of key profiles and associated locks may be selected at random for the fabrication of a particular housing. The housing may be configured to be installed in-line between irrigation controller 116 and the valves. The housing may be designed to be installed below or beside irrigation controller 116, or may be configured for installation within a housing that includes irrigation controller 116. Additionally, the housing for monitoring system 120 may be configured for mounting to a wall or other structure.

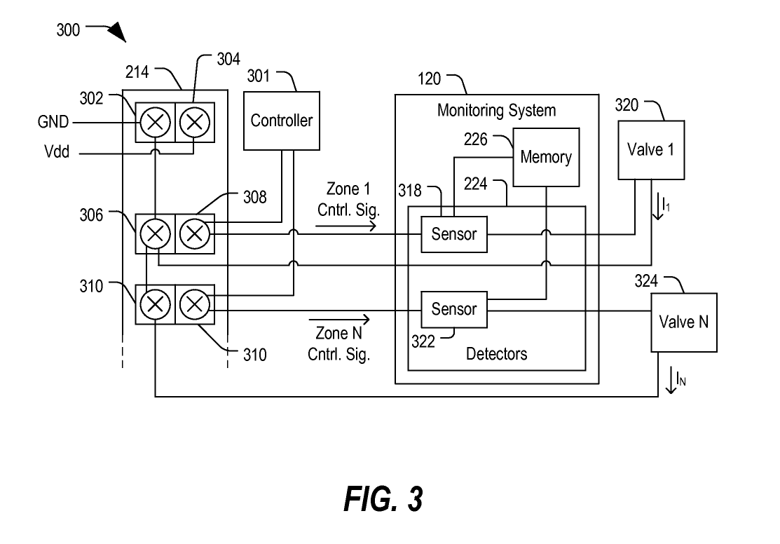

FIG. 3 is a block diagram of a portion 300 of the irrigation system 100 (or 200) according to an embodiment. Portion 300 includes solenoid control signal distribution block 214 coupled to valves 320 and 324 through monitoring system 120. Solenoid control signal distribution block 214 includes threaded fasteners 302, 304, 306, 308, 310, and 312 that are configured to secure electrical conductors or wires to a conductive pad. In the illustrated example, threaded fastener 302 is coupled to an electrical ground and to threaded fasteners 306 and 310. Threaded fastener 304 provides power to switches and other circuitry coupled to the solenoid control signal distribution block 214.

Solenoid control signal distribution block 214 includes fastener 308 coupled to controller 301 to receive a zone control signal, and coupled to valve 320 through monitoring system 120 to provide control signals (labeled “Zone 1 Cntrl. Sig.”). Solenoid control signal distribution block 214 further includes fastener 306 coupled to valve 320 to provide a return current flow path. Solenoid control signal distribution block 214 includes fastener 312 coupled to controller 301 to receive a zone control signal, and coupled to valve 324 through monitoring system 120 to provide control signals (labeled “Zone N Cntrl. Sig.”). Solenoid control signal distribution block 214 further includes fastener 310 coupled to valve 320 to provide a return current flow path. While only two valves 320 and 324 are depicted, the irrigation system 100 may include any number of valves and corresponding irrigation zones by providing control signals. Controller 301 may individually control valves 320 and 324 to deliver water to the zones, independently.

In the illustrated example, controller 301 may include a field programmable gate array (FPGA) and a memory configured to store time and duration data, as well as a timer or clock. Alternatively, controller 301 may include a microcontroller unit (MCU) or general-purpose processor configured to execute instructions to control operation of irrigation system 100. In a particular example, controller 301 may include processor 202, driver circuitry 210 and memory 204 in FIG. 2, as well as other circuitry.

In the illustrated example, monitoring system 120 includes memory 226 and detectors 224 (as described with respect to FIG. 2). In this example, detectors 224 include a first sensor 318 including an input coupled to fastener 308 to receive a control signal, a first output configured to provide data to memory 226 to record or log data related to the control signal, and a second output coupled to an input of valve 320, which has an output coupled to fastener 306. Detectors 224 further include a second sensor 322 having an input coupled to fastener 312 to receive a control signal, a first output configured to provide data to memory 226 to record or log data related to the control signal, and an output coupled to an input of valve 324, which has an output coupled to fastener 310.

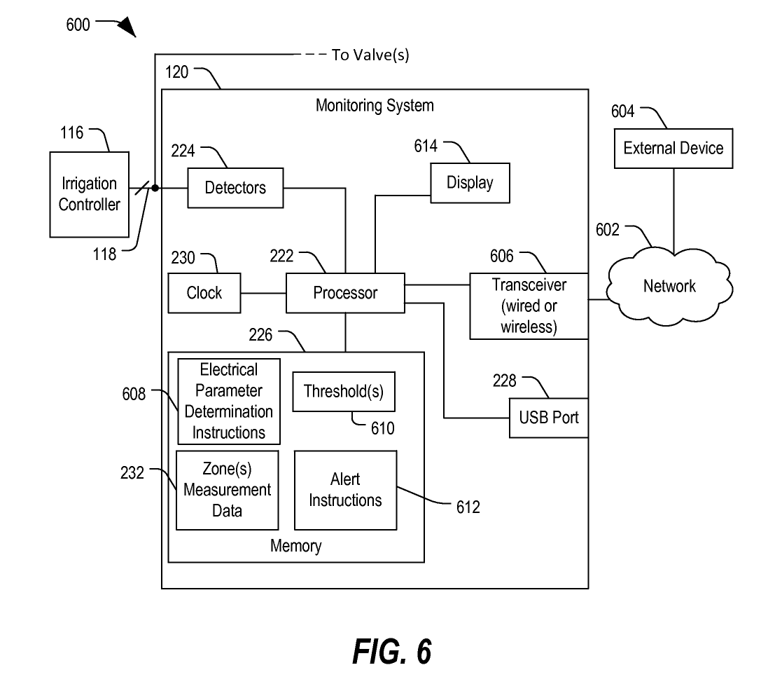

In operation, controller 301 provides a control signal to one of fastener 308 and fastener 310, which control signal is provided via control lines through monitoring system 120 to one of valves 320 and 324. Valves 320 and 324 operate according to the control signals and may provide a return current (labeled “I₁” and “I_{N}”) to fasteners 306 and 310, respectively. In response to the control signal, monitoring system 120 captures samples of the control signal and associated date, time, and other information to produce data related to the control signal, which data is stored in memory 226. The data may include date, time, duration, amplitude (current or voltage), an average current or voltage value, and/or raw data samples. The data may be retrieved by a user at a later time by connecting to USB port 228 (in FIG. 2) or through a wireless communication link (discussed below with respect to FIG. 6.

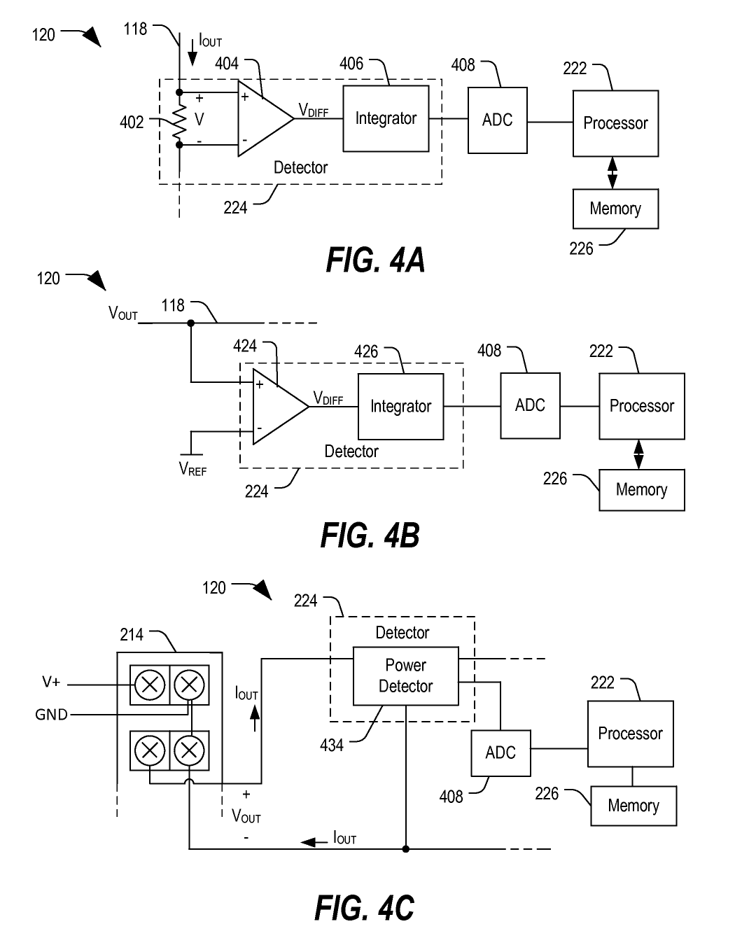

In the illustrated example of FIG. 3, a simplified depiction of monitoring system 120 is shown. However, it should be appreciated that monitoring system 120 may include a processor, analog-to-digital converters, and/or other circuitry to convert measurement signals into digital data for storage in memory 226. Further as mentioned above, monitoring system 120 may be configured to measure an electrical parameter, such as current voltage, power, or another electrical parameter (such as impedance, resistance, capacitance, or another parameter) and may record (log) data corresponding to the measured electrical parameter in memory 226. Examples of circuits to detect electrical parameters that may be used within monitoring system 120 are described below with respect to FIGS. 4A-4C.

FIGS. 4A-4C are diagrams of a portion of the monitoring system of FIGS. 1 and 2, including a current detector (4A), a voltage detector (4B), and a power detector (4C) according to embodiments. In FIG. 4A, monitoring system 120 includes a detector 224 coupled to control line 118. In this example, detector 224 includes a sense resistor 402 coupled between control line 118 and a valve (Valve1, Valve2, and the like, depicted in FIG. 1). Detector 224 further includes an amplifier 404 including inputs configured to receive a voltage across sense resistor 402 and including an output to provide a differential voltage (labeled “V_{DIFF}”) to an input of an integrator 406. Integrator 406 includes an output coupled to an input of an analog-to-digital converter (ADC) 408, which has an output coupled to processor 222. Processor 222 is coupled to memory 226.

In an example, amplifier 404 determines a voltage difference across sense resistor 02. Integrator 406 integrates the differential voltage (“V_{DIFF}”) over time, and provides an integrated value to ADC 408, which digitizes the value and provides the digitized value to processor 222. Processor 222 may compare the digitized value to a threshold and/or may store the digitized value in memory 226. In this particular example, monitoring system 120 monitors an output current (I_{OUT}) over time. In an alternative embodiment, such as that depicted in FIG. 4B, monitoring system 120 may monitor a voltage potential.

In FIG. 4B, detector 224 includes a comparator 424 that has a first input coupled to control line 118, a second input coupled to a reference voltage (V_{REF}), and an output coupled to an input of an integrator 426. Integrator 426 may be the same as integrator 406. Integrator 426 includes an output coupled to ADC 408, which has an output coupled to processor 222, which is coupled to memory 226. In this example, integrator 408 integrates the difference between the input voltage on control line 118 and the reference voltage over time. The reference voltage may be a voltage threshold. The value may be further processed by processor 222 and/or stored in memory 226.

In another example, detector 224 may include a power detector that measures current and voltage over time. One possible example of such a detector is described below with respect to FIG. 4C.

In FIG. 4C, monitoring system 120 includes detector 224 including a power detector 434. Power detector 434 includes an input coupled to a fastener of solenoid control signal distribution block 214 to receive a control signal (labeled “I_{OUT}”), an output coupled to ground, a second output coupled to one of the valves, and a third output coupled to an input of ADC 408. ADC 408 receives an analog signal representing a power level of the control signal and provides a digital output signal corresponding to the analog signal. ADC 408 provides the digital output signal to processor 222, which may process the digital output signal and/or store data corresponding to the digital output signal in memory 226.

In an embodiment, power detector 434 monitors both current and voltage parameters of the control signal to determine a power parameter. Power detector 434 may monitor the power parameter over a period of time.

In FIGS. 4A-4C, the measured electrical parameter may be used to detect when the irrigation controller 116 is malfunctioning or turned off. In an example, if irrigation controller 116 is turned off, monitoring system 120 will detect no control signals on control line 118 for a period of time, which may indicate that a user may have turned off the irrigation system and/or may have turned off a particular zone. Alternatively, the lack of a control signal over a period of time may indicate that the control line 118 has been disconnected or severed.

In another example, monitoring system 120 may capture a plurality of samples of the control signal while the control signal is being applied to a valve associated with a particular zone. Monitoring system 120 stores the samples in memory 226. The samples may represent a particular profile or signature representing operating characteristics of the valve. In some embodiments, monitoring system 120 may process the samples to compare the samples to previously stored samples (such as a known “good” profile). If monitoring system 120 detects a change in the samples related to the previously stored samples, the change may represent a change in an operating characteristic of the solenoid or the valve (which may indicate a problem). For example, the samples may correspond to a current that increases initially to a first level, corresponding to a drive current sufficient to control a solenoid associated with the valve to open, and then decreases to a second level, which corresponds to a holding current level sufficient to maintain the valve in an open state. When the “on-time” duration for the particular valve is reached, the current may be turned off, allowing the valve to close. In this example, if the solenoid is not operating correctly, the solenoid may draw more current than normal, exceeding the first current level or may draw current at the first current level for a longer period of time than normal. Alternatively, if the valve is stuck in an open position, the solenoid may draw less current than normal for either the opening phase or the holding phase.

The current profile may be monitored to detect changes that may indicate solenoid failure or a sticking valve. In another example, the voltage measurements or power measurements may have a particular profile during normal operation, which profile may change when the valve or solenoid is experiencing problems. In such a case, the processor 222 may detect the change in the profile by comparing the measurement profile against a previously recorded measurement profile from memory 226 and may generate an alert when the measurement profile varies from the previously recorded measurement profile. The alert may include a flashing light, an error code on a display of monitoring system 120, an electronic message, or some other indicator.

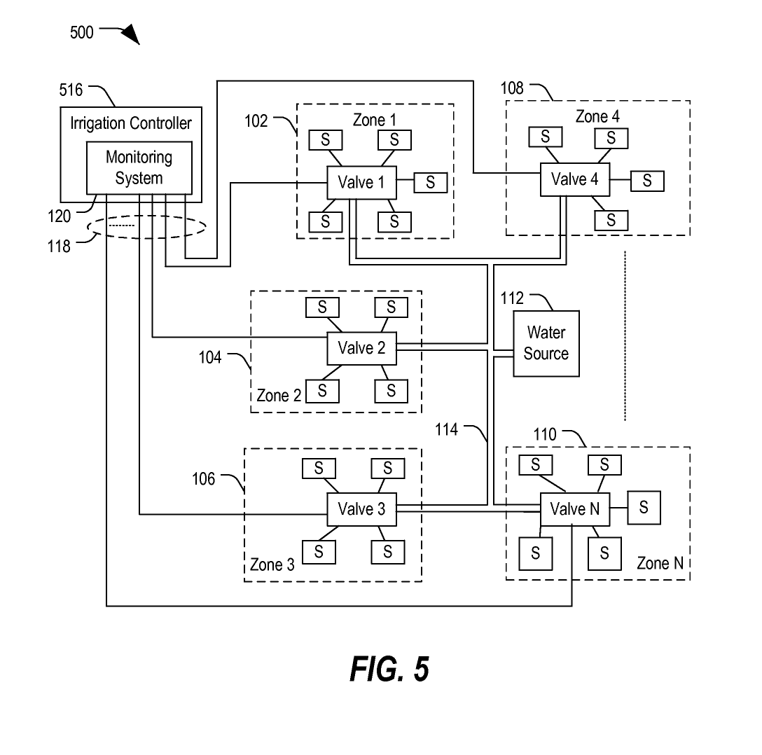

In the embodiments of FIGS. 1-3, monitoring system 120 is depicted as being external to irrigation controller 116 and coupled to control lines 118. It should be understood that monitoring system 120 may be incorporated into the irrigation controller to provide an integrated irrigation control and monitoring system. One possible example is described below with respect to FIG. 5.

FIG. 5 is a block diagram of a second embodiment of an irrigation system 500 including an irrigation controller 516 and an embedded (integrated) monitoring system 120 configured to monitor an electrical parameter associated with the control lines 118. In the illustrated example, irrigation controller 516 includes the same functionality as irrigation controller 116 described in FIGS. 1-3. Monitoring system 120 may be installed on either side of solenoid control signal distribution block 214, between driver circuitry 210 and solenoid control signal distribution block 214 or between solenoid control signal distribution block 214 and the valve (but within the housing of the irrigation controller 516).

In an example, irrigation system 500 may include a port or a wireless transceiver configured to provide data to an external device, either through a wired or wireless communication link. One possible example of a monitoring system 120 configured to communicate with an external device is described below with respect to FIG. 6.

FIG. 6 is a block diagram of an embodiment of an irrigation system 600, such as the irrigation systems 100, 200, 300, and 500 of FIGS. 1-3, and 5 including a transceiver configured to communicate with an external device 604 via a network 602. Irrigation system 600 includes irrigation controller 116 and monitoring system 120, which may be incorporated within irrigation controller 116. Monitoring system 120 includes one or more detectors 224 coupled to control lines 118 from irrigation controller 116. In this example, detectors 224 may include one or more ADCs configured to digitize the analog input and may also include one or more integrators to integrate the detected values over time. Detectors 224 are coupled to a processor 222, which is coupled to memory 226, to USB port 228, and to clock 230. Further, processor 222 is coupled to a transceiver 606, which may communicate with external device 604 through a network 602, which may be a wired network link or a wireless link, such as a Bluetooth® communication link or other short or long-range wireless link.

Memory 226 may store a plurality of instructions that may be executed by processor 222 to control monitoring system 120. Memory 226 stores zone measurement data 232 corresponding to data from detectors 224 for each zone of a plurality of irrigation zones. Memory 226 further stores electrical parameter determination instructions 608 that, when executed, cause processor 226 to determine an electrical parameter, such as a peak level, an average level, a signal profile, or other electrical parameter corresponding to the control signals provided to control lines 118. Memory 226 may also store one or more thresholds 610, which may be used by processor 222 to determine when a measured value is out of range, which may indicate a stuck valve or a solenoid failure. In an embodiment, the one or more thresholds 610 may include sample profiles representing the current/voltage draw of each valve in a known “good” operating state.

Memory 226 may also store alert instructions 612 that, when executed, cause processor 222 to determine when a measurement exceeds one or more of the thresholds 610 and to generate an alert signal in response to determining when the measurement exceeds at least one of the thresholds 610. Processor 222 may provide the alert signal to USB port 228 and/or to transceiver 606 for communication to external device 604. Further, processor 222 may be coupled to a display 614, which may be configured to display text and/or images to indicate a state of the monitoring system and/or to indicate when a particular error or problem has been detected.

In an embodiment, external device 604 may be a computing device at a remote location that is configured to monitor operation of one or more irrigation systems 600. In another embodiment, external device 604 may be a portable computing device, such as a smart phone or tablet computer, that is configured to communicate with transceiver 606 of monitoring system 120 when the portable computing device is carried within range of transceiver 606. In another embodiment, transceiver 606 may be configured to utilize an existing local area network, such as a short-range wireless network, to send an electronic message to external device 604 through network 602. In an example, transceiver 606 may communicate with a wireless router to establish a connection and to receive an Internet protocol (IP) address, which may be used by transceiver 606 to establish a connection to network 604 and to communicate measurement data to external device.

In an embodiment, monitoring system 120 may generate an alert when irrigation controller 116 fails to activate one or more zones according to a pre-configured watering schedule. Alternatively, monitoring system 120 may generate the alert when the irrigation controller 116 fails to activate a zone a pre-determined number of times during a time period, such as over a two week time period. In still another example, monitoring system 120 may detect a change in operation of a particular valve, based on increased or diminished current drawn by the solenoid, which may provide an early indication of a problem, allowing a monitoring service to rectify a failing valve or solenoid before landscaping is affected.

In an alternative embodiment, monitoring system 120 may store raw measurement data and provide the raw measurement data to the external device 604, which may be configured to process the data. In such an example, monitoring system 120 may provide the raw measurement data in a format that can be readily imported into a spreadsheet or other program for further processing.

In an embodiment, the alert may be a text message, an automated voice message, an email message, or another type of alert. The alert may include an identifier indicating the affected zone, allowing maintenance personnel to quickly and efficiently identify the source of the problem and to remedy the situation. In a particular embodiment, the alert may be a short message service (SMS) text message, which may be sent through a network, such as a cellular or digital communications network, which may be used for mobile telephone communications and other data communications.

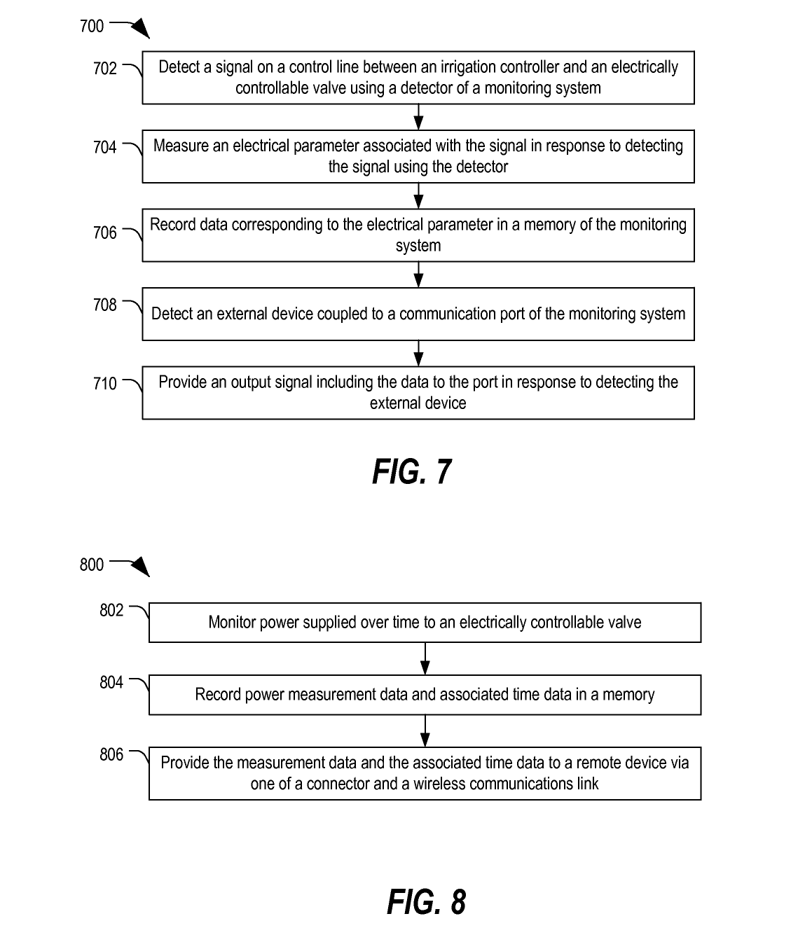

FIG. 7 is a flow diagram of an embodiment of a method 700 of recording data corresponding to an electrical parameter monitored by the monitoring system of FIGS. 1-3, and 5-6. At 702, a detector of a monitoring system detects a signal on a control line between an irrigation controller and an electrically controllable valve. The monitoring system may be coupled to the control line and/or may be integrated within an irrigation controller.

Advancing to 704, the monitoring system measures an electrical parameter associated with the signal in response to detecting the signal using the detector. The electrical parameter may include at least one of a current level, a voltage level, a power level, and an electrical signature corresponding to the power supplied to or drawn by a solenoid of a valve of an irrigation system. Proceeding to 706, the monitoring system records data corresponding to the electrical parameter in a memory of the monitoring system. The data may include a time stamp (date/time) of the data collection, a duration, amplitude, and other information.

At a later time, the monitoring system may detect an external device coupled to a communication port of the monitoring system, at 708. In an example, the external device may be coupled to the monitoring system through a USB connector. Moving to 710, the monitoring system provides an output signal including the data to the port in response to detecting the external device.

In an alternative embodiment, the monitoring system may detect an external device through negotiation of a wireless communication link, such as a Bluetooth® communication link. In this alternative example, the monitoring system may communicate the output signal to the external device through the wireless communication link in response to detecting the external device.

FIG. 8 is a flow diagram of an embodiment of a method 800 of providing measurement data and associated time data from an irrigation system to a remote device. At 802, the power supplied over time to an electrically controllable valve is monitored. Advancing to 804, the power measurement data and associated time data are recorded in a memory. Proceeding to 806, the measurement data and associated time data are provided to a remote (external) device via one of a connector and a wireless communications link.

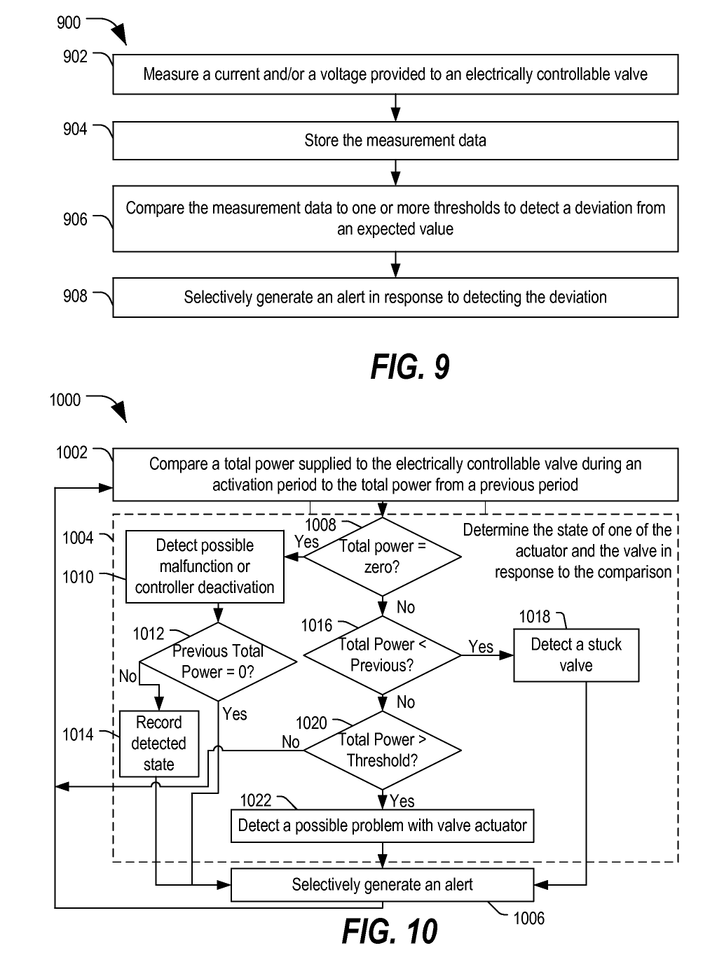

FIG. 9 is a flow diagram of an embodiment of a method 900 of selectively generating an alert in response to detecting a deviation in the measurement data of an irrigation system. At 902, a current and/or a voltage provided to an electrically controllable valve is measured. As mentioned above, monitoring system may capture a plurality of measurement samples during operation of a particular zone. Advancing to 904, the monitoring system stores the measurement data. Continuing to 906, the monitoring system compares the measurement data to one or more thresholds to detect a deviation from an expected value. Proceeding to 908, the monitoring system selectively generates an alert in response to detecting the deviation.

FIG. 10 is a flow diagram of an embodiment of a method 1000 of generating an alert in response to detecting a state of one of an actuator and a valve of an irrigation system. At 1002, a total power supplied to the electrically controllable valve during an activation period is compared to the total power from a previous activation period. In an embodiment, monitoring system 120 captures multiple samples during operation of a particular valve. The multiple samples represent a power profile for the valve, which can be compared to a previously stored power profile corresponding to a known “good” state. As used herein, the term “known ‘good’ state” refers to proper operation of the valve under normal operating conditions. If a valve is in a “known ‘good’ state, the valve operates according to manufacturer specifications in response to the control signals from an irrigation controller.

Advancing to 1004, the state of one of the actuator and the valve is determined in response to the comparison. In the above-example, the state may be determined from total power supplied to the actuator or the valve. In another example, the state may be determined by comparing one of a current, voltage, impedance, or other electrical parameter defining a control signal signature to a pre-determined signature profile to determine the state. Continuing to 1006, the monitoring system selectively generates an alert. The monitoring system generates an alert when the current is less than measured device signature differs from the pre-determined signature by more than a threshold amount. The method 1000 then returns to 1002 and a total power supplied to a next electrically controllable valve during the activation period is compared to a total power from a previous period.

Determination of the state of the actuator and/or the valve may include a number of comparisons. In the illustrated example, at 1008, if the total power supplied to the electrically controllable valve during the activation period is equal to zero, method 1000 advances to 1010 and a possible malfunction or controller deactivation is detected. Continuing to 1012, if the previous total power (i.e., the total power provided in a previous activation period) was not equal to zero, the method advances to 1014 and the detected state is recorded in a memory. The method 1000 continues to 1006 and an alert may be generated. Returning to 1012, if the previous total power was also equal to zero, the method advances to 1006 and an alert may be generated. In a particular example, blocks 1008, 1010, 1012, and 1014 represent a possibility that a particular actuator may not receive a control signal for multiple time periods, indicating that the irrigation system failed to activate that particular zone for multiple time periods. The monitoring system may be configured to generate an alert only after a pre-determined number of time periods have expired without detecting a control signal to activate a particular zone.

Returning to 1008, if the total power is not equal to zero, the method 1000 advances to 1016 to determine if the total power supplied to the electrically controllable valve is less than a previous total power. If yes, the method advances to 1018 and a stuck valve is detected. In this example, it may use less power to open a valve that is already in a partially open state than it would take to open a valve that starts from a fully closed state. If, at 1016, the total power is not less than the previous total power, method 1000 advances to 1020 to determine if the total power is greater than a threshold power value. If not, the method 1000 returns to 1002. Otherwise, the method 1000 proceeds to 1022 and the monitoring system detects a possible problem with the valve actuator, such as a stuck valve or a faulty or failing solenoid.

In embodiments of the monitoring system and methods described above with respect to FIGS. 1-10, the monitoring system may capture data corresponding to the date, time, and duration of a particular control signal and corresponding to one or more electrical parameters associated with the control signal. The data may be stored in memory 226 in a table format that can be imported into a spreadsheet computing application, such as Microsoft® Excel® or other spreadsheet or other software packages that may be used for data analysis. The data may include a date, time, start time of each zone, duration data corresponding the amount of time with which current is sent to each zone, and the end time of each zone, as well as one or more sampled values corresponding to electrical parameters of the control signal during the duration. The monitoring system may also detect and record power outages, dates and times when the data has been accessed, flow meter data from a fluid flow sensor, rain gauge data from a rain gauge coupled to the irrigation controller, data from individual flow sensors, temperature data, and other data.

In a particular embodiment, the monitoring system may be installed and/or removed and placed into a new enclosure, and a bus-bar (such as a distribution block) may be installed in its place to minimize reconnection work.

The monitoring system may be used to provide data logging functionality for standard irrigation control intervals. The monitoring system may be configured to monitor multiple irrigation zones and may include multiple different communication options, including wired or wireless networking, short-range wireless communications, and/or wired communications.

Although the present invention has been described with reference to preferred embodiments, workers skilled in the art will recognize that changes may be made in form and detail without departing from the scope of the invention.

What is claimed is:

1. A monitoring system configured to monitor electrical signals in an irrigation system, the monitoring system comprising:
a memory; and
a detector coupled to an irrigation control line that is configured to provide control signals to an actuator within the irrigation system, the detector configured to sense an electrical parameter of the control signals and to store data related to the electrical parameter in the memory.

2. The monitoring system of claim 1, further comprising a processor coupled to the detector and the memory, the processor configured to store the data together with a date, a start time, an end time, and a zone indicator in the memory.

3. The monitoring system of claim 2, wherein the memory further includes instructions that, when executed by the processor, cause the processor to compare the data to a threshold and to detect an error when the data exceeds the threshold.

4. The monitoring system of claim 2, wherein the memory further includes instructions that, when executed by the processor, cause the processor to compare the data to a profile and to detect an error when the data differs from the profile.

5. The monitoring system of claim 2, further comprising a display coupled to the processor; and
wherein the processor is configured to provide a message to the display indicating at least one of a state of the monitoring system and an error associated with at least one valve of the irrigation system.

6. The monitoring system of claim 2, further comprising a transceiver coupled to the processor and configured to communicate the data to an external device.

7. The monitoring system of claim 6, wherein the transceiver comprises a wireless transceiver adapted to communicate the data to the external device through a wireless communications link.

8. The monitoring system of claim 6, wherein the transceiver includes a USB port configured to receive a USB connector, to detect the USB connector in the USB port, and to communicate the data to the USB port in response to detecting the USB connector.

9. The monitoring system of claim 1, wherein the electrical parameter comprises at least one of a voltage, a current, and a power level.

10. An irrigation system comprising:
an irrigation controller coupled to a plurality of irrigation control lines and configured to selectively apply control signals to one or more of the plurality of irrigation control lines to selectively activate a plurality of watering zones of an irrigation system; and
a monitoring system coupled to the plurality of irrigation control lines, the monitoring system including a memory and at least one sensor, the monitoring system configured to sense at least one electrical parameter associated with the plurality of irrigation control lines during an irrigation operation using the at least one sensor and to store data corresponding to the at least one electrical parameter in the memory.

11. The irrigation system of claim 10, wherein the monitoring system further includes a USB port configured to receive a USB connector, the monitoring system configured to detect the USB connector in the USB port and to provide the data to the USB port in response to detecting the USB connector.

12. The irrigation system of claim 10, wherein the monitoring system further includes a wireless transceiver configured to transmit the data to an external device through a wireless communication link.

13. The irrigation system of claim 12, further comprising a processor coupled to the at least one sensor and to the memory, the processor configured to compare the data to a threshold and to selectively provide an alert to the wireless transceiver in response to the comparison.

14. The irrigation system of claim 12, further comprising a processor coupled to the at least one sensor and the memory, the processor configured to compare the data to a profile stored in the memory and to selectively provide an alert to the wireless transceiver in response to the comparison.

15. The irrigation system of claim 10, wherein the monitoring system is configured to detect one of a failing solenoid and a stuck valve in response to sensing the at least one electrical parameter.

16. The irrigation system of claim 10, wherein the at least one electrical parameter comprises at least one of a voltage level, a current level, and a power level.

17. A method of monitoring an irrigation system, the method comprising:
detecting a signal on a control line of an irrigation system;
measuring at least one electrical parameter associated with the signal in response to detecting the signal; and
recording data corresponding to the at least one electrical parameter in a memory.

18. The method of claim 17, further comprising:
detecting an external device;
establishing a communication link with the external device; and
communicating the data to the external device through the communication link.

19. The method of claim 18, wherein detecting the external device comprises detecting one of a network connection using a network transceiver and a USB connector at a USB port of a monitoring system.

20. The method of claim 17, wherein recording the data comprises:
determining a date;
determining a start time;
determining an end time; and
recording the date, the start time, the end time, and the at least one electrical parameter in the memory.
